(19) United States
(12) Patent Application Publication
(10) Pub. No.: US 2011/0182037 A1
(43) Pub. Date: Jul. 28, 2011

(54) CARD DEVICE

(75) Inventor: Akitomi Katsumura, Aichi (JP)

(73) Assignee: SONY CORPORATION, Tokyo (JP)

(21) Appl. No.: 13/008,415

(22) Filed: Jan. 18, 2011

(30) Foreign Application Priority Data
Jan. 28, 2010 (JP) 2010-017116

(51) Int. Cl. H05K 7/00

(52) U.S. Cl. 361/728

(57) ABSTRACT

A card device capable of improving mechanical strength of a mounting substrate with a simple structure is provided. A memory card includes the mounting substrate and a semiconductor package in a package. An electronic component such as a communication component on the mounting substrate is covered with a protective member having an electromagnetic shield function. The protective member is formed by drawing process of a sheet metal, has a containable space by a ceiling section and a side wall, and has a curve section at a joint section between an all rim of the ceiling section and the side wall. A flange is provided on the bottom end of the side wall, and the flange is solder-jointed with a ground region of the mounting substrate. In the protective member having the foregoing structure, stress hardly concentrates locally. Thus, its mechanical strength is large, and rigidity of the mounting substrate is increased.

### BACKGROUND OF THE INVENTION

1. Field of the Invention

The present invention relates to a card device such as a memory card having a memory function and a communication card having a communication function such as close wireless transfer, particularly to a card device suitable for the case using a thin mounting substrate with low strength.

2. Description of the Related Art

In an electronic device such as a mobile phone, a PDA (Personal Digital Assistant), and a portable game machine, a card device for adding various functions such as a memory card (for example, Japanese Unexamined Patent Application Publication No. 2006-92094) and a data communication card (for example, Japanese Unexamined Patent Application Publication No. 2002-329185) is used. The thickness of such a kind of card has been decreased along with miniaturization of a machine body.

### SUMMARY OF THE INVENTION

As the thickness of the card is decreased, the strength is lowered by just that much and the card is easily deformed due to external stress. To secure stable operation of the card, the card itself should have given mechanical strength (rigidity) to avoid trouble in electric operation even if the card is twisted or bent under given load. However, in such a kind of card, a cabinet (case) and a mounting substrate are formed significantly thin to secure the height in the cabinet (that is, the height of an electronic component). It is difficult to secure the mechanical strength by itself, and some reinforcement measures should be taken separately.

In the past, as the reinforcement measures, a method (first reinforcement method) to give rigidity by hardening mounted components such as an IC (integrated circuit) and a chip by a thermoset resin and a method (second reinforcement method) to secure rigidity by a cabinet in which a sheet metal is outserted (or inserted) have existed.

However, in the foregoing first reinforcement method, there have been disadvantages that coating region of the resin is limited, strength of the mounted components is not stable depending on the coating amount of the resin, and stress is applied to the substrate at the time of hardening the resin. Further, there have been disadvantages that equipment investment for coating with the resin is necessitated, controlling the resin is necessitated in the case of mass production, and segregation disposal is necessitated. Meanwhile, in the second reinforcement method, there have been disadvantages that since a resin and the sheet metal are not jointed materially, linkage should be made so that the sheet metal is held by the resin, and thus a large space should be consumed. In addition, coating should be made so that the sheet metal is not exposed apparently. Further, there have been disadvantages that durability of the coating should be secured, and a structure to connect the sheet metal to GND (ground) of the substrate is necessitated as an electrostatic measurement, and thus the second reinforcement method is not practical.

In view of the foregoing disadvantages, in the invention, it is desirable to provide a card device capable of improving mechanical strength of a mounting substrate with a simple structure.

According to an embodiment of the invention, there is provided a card device including a package; a mounting substrate on which an electronic component is mounted and which is contained in the package; and a protective member that is jointed with the mounting substrate so as to cover at least part of the electronic component. The protective member forms a containable space by a ceiling section and a side wall, has a curve section at a joint section between a rim of the ceiling section and the side wall, and shows higher rigidity than that of the mounting substrate. The protective member is able to be formed by drawing process (deep drawing process) of a sheet metal such as SUS.

In the card device, the all rim of the ceiling section of the protective member is jointed with the side wall through the curve section. Thus, stress does not concentrate or hardly concentrates locally in the protective member, and its mechanical strength is large. In addition, the protective member has resistance properties to external force from all directions. Further, in the card device, since the protective member is jointed with the mounting substrate, rigidity is given to the mounting substrate.

In the card device according to the embodiment of the invention, the electronic component on the mounting substrate is protected by the protective member having the structure with which stress hardly concentrates thereon locally. Thus, while the shield function of the electronic component by the protective member is demonstrated, mechanical strength of the mounting substrate is able to be improved without using a separate reinforcement means such as a thermoset resin.

Other and further objects, features and advantages of the invention will appear more fully from the following description.

### BRIEF DESCRIPTION OF THE DRAWINGS

FIG. 1 is an exploded perspective view of a memory card according to an embodiment of the invention.

FIGS. 2A and 2B are exploded perspective views of an electronic circuit section out of the memory card of FIG. 1.

FIG. 3 is a perspective view of a protective member.

FIG. 4 is a cross sectional view illustrating a mounting state of the protective member.

FIG. 5 is a perspective view for explaining stress concentration on a protective member (comparative example) formed by bending process.

FIGS. 6A and 6B are perspective views for explaining a soldering region of the protective member to a flange.

FIG. 7 is a view for explaining a joint section between a semiconductor package and a mounting substrate.

FIG. 8 is a view illustrating a cross sectional structure in the longitudinal direction of the memory card.

FIGS. 9A and 9B are views for explaining stress applied to the memory card.

FIGS. 10A and 10B are charts for explaining effect of the invention in comparison with the existing method (reinforcement by a thermoset resin).

FIG. 11 is a block diagram for explaining a signal processing system in the memory card.

FIG. 12 is a block diagram for explaining a signal processing system of a digital still camera.

FIG. 13 is a view for explaining a mounting state of the memory card to the digital still camera.

### DETAILED DESCRIPTION OF THE PREFERRED EMBODIMENT

An embodiment of the invention will be described with reference to the drawings. In this embodiment, as a card device of the invention, a description will be given by taking a memory card having both a memory function and a wireless communication function as an example. The description will be given in the following order.

1. Explanation of a structure of the memory card
2. Explanation of action and effect of the memory card
3. Explanation of an application example of the memory card

1. Explanation of a Structure of the Memory Card

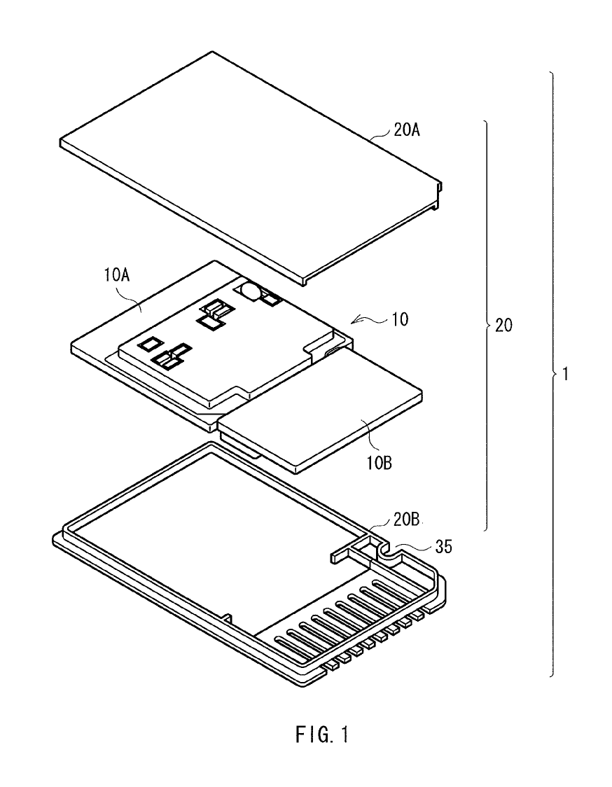

FIG. 1 illustrates a view of a disassembled memory card 1 according to an embodiment of the invention. In the memory card 1, an electronic circuit section 10 is contained in a package 20. The memory card 1 has a flat shape as a whole. As described later, in the case where the memory card 1 is loaded into various electronic devices such as a digital still camera, the memory card 1 demonstrates a memory function and a wireless communication function.

The package 20 is composed of, for example, a pair of a first cabinet 20A and a second cabinet 20B. The inner face of the first cabinet 20A and the inner face of the second cabinet 20B are opposed and jointed with each other, and therefore an internal space is formed. The electronic circuit section 10 is contained in such an internal space.

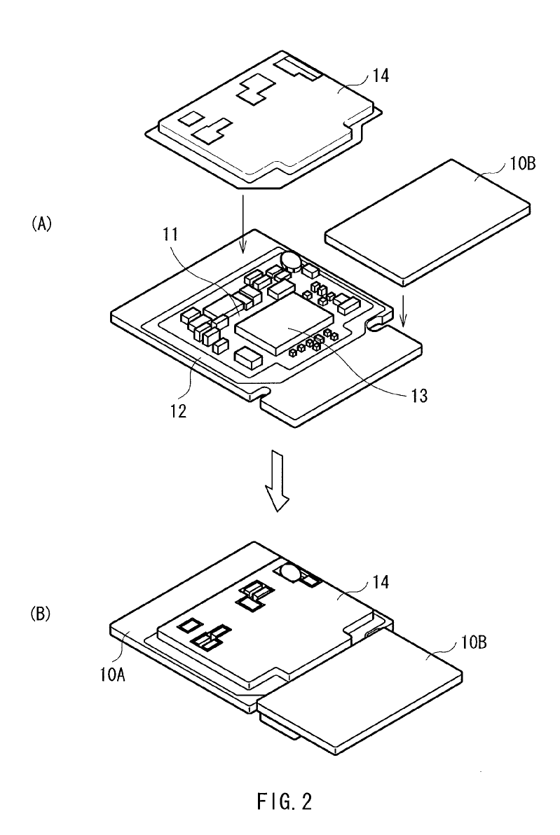

For example, as the disassembled state in FIGS. 2A and 2B, the electronic circuit section 10 includes a mounting substrate 10A and a semiconductor package 10B. The mounting substrate 10A and the semiconductor package 10B are connected by solder or the like.

The mounting substrate 10A is formed from a resin such as a glass-containing epoxy resin, copper pattern or the like, and has a thickness of, for example, from 0.15 mm to 0.3 mm both inclusive. On the front face of the mounting substrate 10A, a mounting region 11 is provided in the central section, and a ground region (GND) 12 is provided in a position around the periphery of the mounting region 11. In the mounting region 11, various electronic components such as a communication component 13 for close wireless transfer are mounted. Close wireless transfer technology by the communication component 13 is used for close wireless communication such as personal authentication and a cardkey function at, for example, central frequency of 4.48 GHz. Although mounting on the rear face is available in the mounting substrate 10A, in this embodiment, most electronic components are mounted on the face (front face) on the side connected with the semiconductor package 10B. In particular, it is preferable that electronic components having a certain height or more are mounted on the front face of the mounting substrate 10A as the semiconductor package 10B is.

The memory card 1 further includes a protective member 14 having an electromagnetic shield function. The electronic components such as the communication component 13 mounted on the mounting substrate 10A are protected (shielded) from being affected by unnecessary electromagnetic wave, static electricity and the like by the protective member 14. In this embodiment, the protective member 14 is formed by drawing (deep drawing) process of a conductive sheet metal such as stainless (SUS). Therefore, the protective member 14 has mechanical strength to external force in addition to an electromagnetic shield function. It is preferable that the protective member 14 is provided with plating treatment after the sheet metal is press-segmentalized in order to perform solder joint to the mounting substrate 10A as described later.

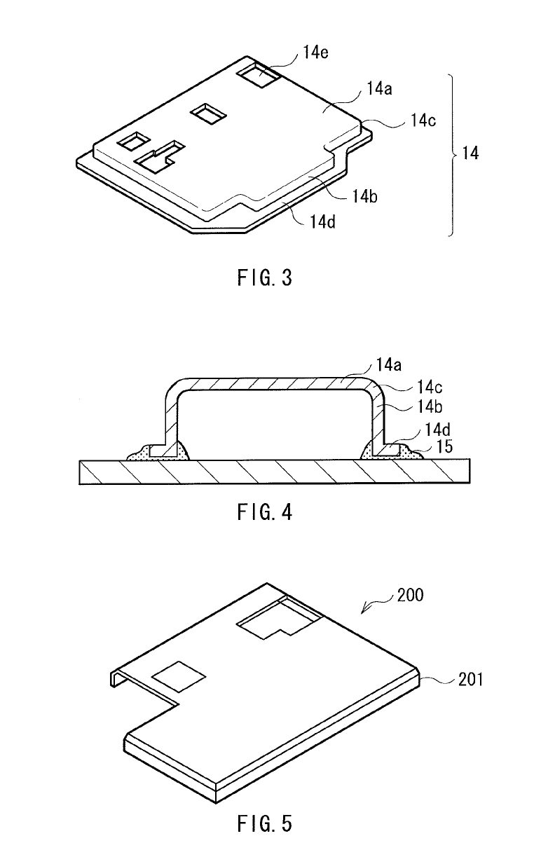

As illustrated in FIG. 3, for example, the protective member 14 has a rectangular flat ceiling section 14a and a frame-like side wall 14b. The protective member 14 forms a containable space for containing the electronic component such as the communication component 13 by the ceiling section 14a and the side wall 14b. Joint section between all rim of the ceiling section 14a and the side wall 14b is a curve section 14c through which the ceiling section 14a and the side wall 14b are smoothly jointed. The protective member 14 further has a flange 14d at the bottom end of the side wall 14b, and the flange 14d is in parallel with the ceiling section 14a. The ceiling section 14a is provided with an aperture 14e having a loophole structure for some electronic components having a large height. As the cross sectional structure illustrated in FIG. 4, in the protective member 14, the flange 14d is jointed with the ground region 12 of the mounting substrate 10A by, for example, solder 15.

In a protective member 200 formed by bending process illustrated in FIG. 5, there has been a disadvantage that stress easily concentrates on many corner sections 201, rigidity is low as a whole, and the member is vulnerable to deformation. Meanwhile, the protective member 14 of this embodiment is formed by drawing process of the sheet metal as described above, and the all rim of the ceiling section 14a is connected with the side wall 14b through the curve section 14c. Thus, stress hardly concentrates locally in the protective member 14, and its mechanical strength is large (FIG. 3). In other words, the protective member 14 has high rigidity as a whole structure, and has resistance properties to external force from all directions. In addition, the flange 14d of the protective member 14 is jointed with the ground region 12 of the mounting substrate 10A by solder, and therefore rigidity is given to the thin mounting substrate 10A having small mechanical strength. Therefore, even if the first cabinet 20A is dented by external force such as twisting and bending, the communication component 13 and the like are able to be prevented from being broken.

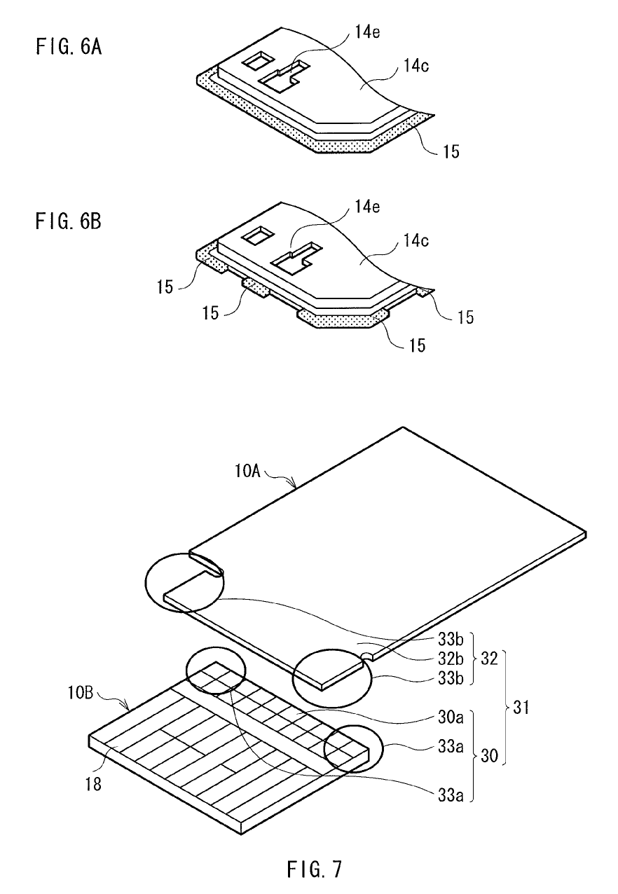

In order to exclude cuts (location on which stress concentrates) that cause solder crack, as illustrated in FIG. 6A, soldering with the solder 15 is preferably performed for all rim of the flange 14d of the protective member 14. However, since the protective member 14 formed by drawing process of the sheet metal has high rigidity, in the case where stress supposed to be applied to the relevant memory card 1 is low, partial joint may be applicable as illustrated in FIG. 6B instead of all rim joint.

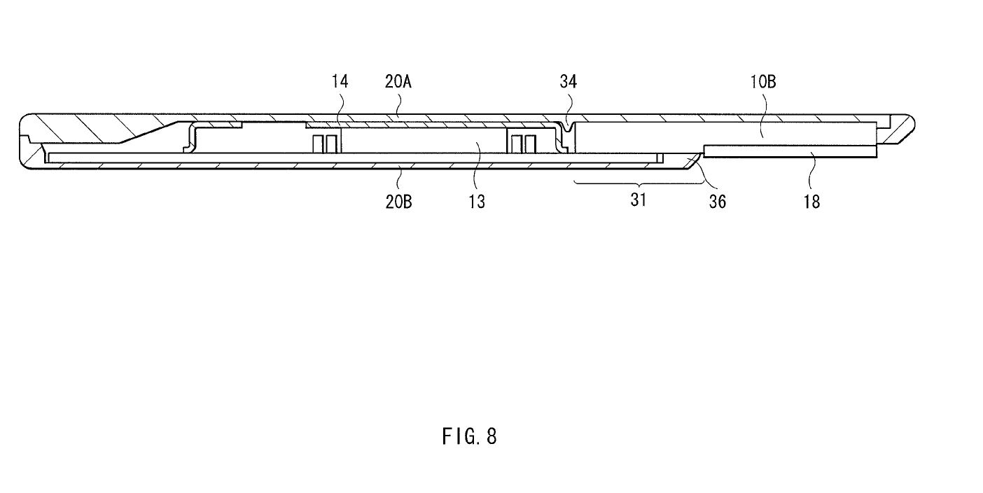

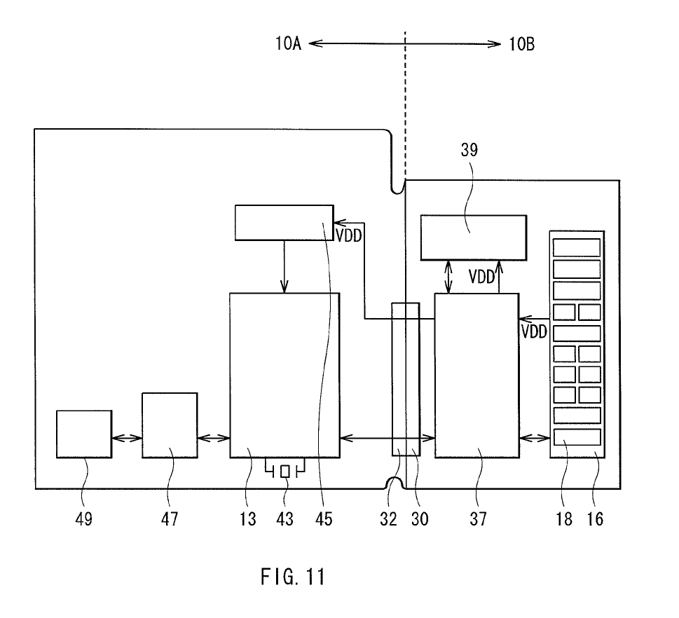

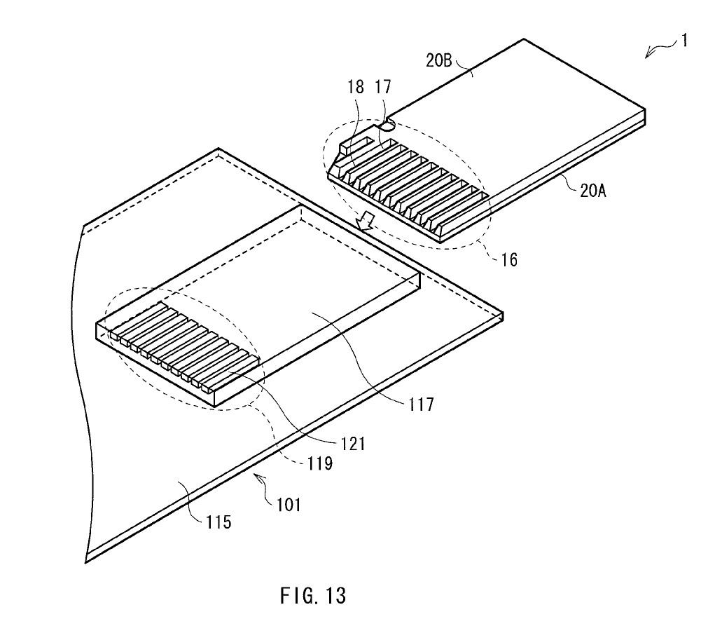

The semiconductor package 10B is a semiconductor device into which a semiconductor chip is enclosed by a resin. In the semiconductor package 10B, a controller section 37 and a memory section 39 are formed (refer to FIG. 11). Further, as illustrated in FIG. 13, a card side connector section 16 is formed in the semiconductor package 10B. As described later, a plurality of grooves 17 having a loophole structure are formed in the second cabinet 20B. A card side terminal 18 is provided in the semiconductor package 10B in the bottom face section of the grooves 17. The section where the card side terminal 18 is provided is a face on the side where the semiconductor package 10B is connected with the mounting substrate 10A, and is a section exposed outside due to overlap (refer to FIG. 8).

The semiconductor package 10B and the mounting substrate 10A are stacked so that only each part thereof is overlapped by shift in the longitudinal direction. The communication component 13 is mounted on the face side where the mounting substrate 10A is jointed with the semiconductor package 10B. Further, it is often the case that the thickness of the semiconductor package 10B is large. Accordingly, in this embodiment, the space for arranging the communication component 13 is able to be sufficiently secured.

Further, the card side terminal 18 is not provided in the mounting substrate 10A, but is provided in the semiconductor package 10B. Thus, it is able to prevent, for example, an event the card side terminal 18 and the semiconductor package 10B in which the card side terminal 18 is provided, from being warped, for example. In other words, the semiconductor package 10B is formed comparatively thick, and is made of a resin material having comparatively higher strength than that of the mounting substrate 10A. Since the card side terminal 18 is provided in such a semiconductor package 10B, position shift of the card side terminal 18 and contact failure between the card side terminal 18 and a slot side terminal 121 (FIG. 13) do not occur due to warp or the like.

FIG. 7 illustrates a method of jointing between the semiconductor package 10B and the mounting substrate 10A. The semiconductor package 10B and the mounting substrate 10A are jointed that the semiconductor package 10B and the mounting substrate 10A are overlapped each other at a connection section 31. In the semiconductor package 10B, a plurality of package side terminals 30 for transferring an information signal to the mounting substrate 10A are formed. The package side terminals 30 are connected with the controller section 37 as described later. In the mounting substrate 10A, a plurality of substrate side terminals 32 are formed in a position corresponding to the package side terminals 30. The substrate side terminals 32 are electrically connected with the communication component 13 mounted on the mounting substrate 10A. In other words, the controller section 37 in the semiconductor package 10B is electrically connected with the communication component 13 mounted on the mounting substrate 10A thorough the package side terminals 30 and the substrate side terminals 32.

Further, in order to reinforce joint between the semiconductor package 10B and the mounting substrate 10A, a reinforcing land 33 is provided separately from a package side land 30a and a mounting substrate side land 32b having a general size. The reinforcing land 33 is one terminal out of the package side terminals 30 and the substrate side terminals 32, and is a terminal located in the respective most end sections of the package side terminals 30 and the substrate side terminals 32. The reinforcing land 33 is a terminal having a larger area than that of the other terminals (the package side land 30a and the mounting substrate side land 32b) out of the package side terminals 30 and the substrate side terminals 32. The reinforcing land 33 on the semiconductor package 10B side is referred to as a package side reinforcing land 33a, and the reinforcing land 33 on the mounting substrate 10A side is referred to as a mounting substrate side reinforcing land 33b. Since the area of the terminal is large, the reinforcing land 33 is able to reinforce joint between the semiconductor package 10B and the mounting substrate 10A. Examples of joint method by the reinforcing land 33 include a method by using solder. Examples of the resin for enclosing a semiconductor chip into the semiconductor package 10B include a thermoset resin such as an epoxy resin.

The first cabinet 20A and the second cabinet 20B that compose the package 20 are formed from, for example, a thermoplastic resin such as polycarbonate and ABS (Acrylonitrile Butadiene Styrene), but the material thereof is not limited to the resin. The first cabinet 20A and the second cabinet 20B have a frame section toward the inner side (circuit section 10 side) at the rim of the flat section having a certain area respectively. In the case where the first cabinet 20A and the second cabinet 20B are jointed with each inner side opposed to each other, the containable space for containing the electronic circuit section 10 is formed therein. The first cabinet 20A and the second cabinet 20B are jointed by, for example, welding, but fastening means such as bolt and nut and a screw may be used. Further, the first cabinet 20A and the second cabinet 20B may be formed integrally by using injection molding.

On the front face of the flat section of the first cabinet 20A, various display is able to be made by, for example, printing. As illustrated in the cross sectional structure in the longitudinal direction of FIG. 8, a defining section 34 is provided in the first cabinet 20A. The defining section 34 contributes to decreasing warp and improving strength of the first cabinet 20A. The defining section 34 also contributes to positioning and fixing the semiconductor package 10B and the protective member 14.

In the second cabinet 20B, the plurality of grooves 17 having a loophole structure are formed in one side in the longitudinal direction of the flat face. A concave section 35 is provided near the grooves 17 on the second cabinet 20B (refer to FIG. 1). The concave section 35 functions to prevent the memory card 1 from slipping through a slot 117 on the electronic device side described later.

A support section 36 is provided at the end in the longitudinal direction of the second cabinet 20B (FIG. 8). The support section 36 has a function to position and fix the mounting substrate 10A in the longitudinal direction, and functions to support the semiconductor package 10B. In other words, the support section 36 has a function to prevent the semiconductor package 10B from being bent downward, and functions to aid joint by the connection section 31.

As illustrated in FIG. 8, the height of the communication component 13 and the protective member 14 is preferably equal to or is slightly lower than the height of the semiconductor package 10B. It leads to an advantage that a dent or the like is not necessarily provided particularly for the first cabinet 20A. If the dent or the like is provided in the first cabinet 20A, the height of the communication component 13 and the protective member 14 is able to be higher than the height of the semiconductor package 10B.

2. Action and Effect of the Memory Card

A description will be given of action and effect of the memory card 1 of this embodiment.

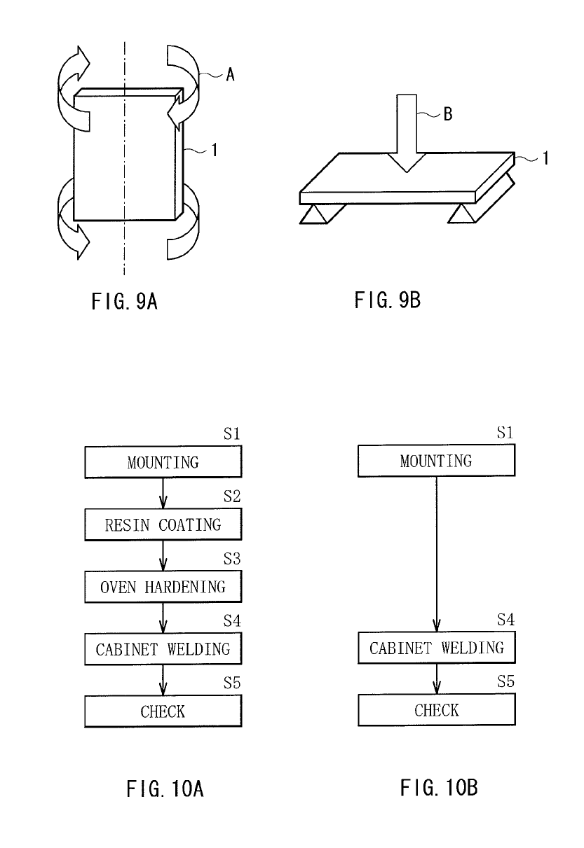

Torsional force A (FIG. 9A) and bend force B (FIG. 9B) act on such a kind of card in loading the card into the slot on the electronic device side. At this time, there is a possibility that the internal mounting substrate 10A is deformed, solder in the mounting section is destroyed, and electric trouble occurs as well. The first cabinet 20A, the second cabinet 20B, and the mounting substrate 10A are respectively formed thin, for example, about from 0.1 to 0.2 mm both inclusive and from 0.15 to 0.3 mm both inclusive in order to secure the height of the mounted components, and thus it is difficult to secure strength by themselves. Meanwhile, in this embodiment, the protective member 14 formed by drawing process of the sheet metal is jointed with the mounting substrate 10A by the solder 15 as described above. Thus, the mounting substrate 10A substantially functions as one rigid body, and the solder in the mounting section is not destroyed. In other words, in this embodiment, while the shield function is demonstrated by the protective member 14, mechanical strength of the memory card 1 is able to be improved.

FIGS. 10A and 10B illustrate advantages of the manufacturing steps of the memory card 1 in comparison with the existing method. In the existing method of securing rigidity by hardening with the use of a thermoset resin, as illustrated in FIG. 10A, after the step of mounting an electronic component such as the communication component 13 (step S1) and the steps of coating with the thermoset resin and hardening the thermoset resin (steps S2 and S3), the first cabinet and the second cabinet are welded (step S4). Thereafter, inspection such as checking operation is performed (step S5). Meanwhile, in this embodiment, as illustrated in FIG. 10B, an equipment, initial setup at the beginning, waste disposal and the like for coating with the resin are not necessitated.

In addition, in this embodiment, since the flange 14d of the protective member 14 is directly connected to the ground region 12 by solder, electrostatic measure is facilitated. Further, the strength of the mounting substrate 14A is increased, it is not necessary to specially increase strength, for example, by forming the package 20 (the first cabinet 20A and the second cabinet 20B) from a sheet metal. In addition, it is not necessary to decorate the package 20, for example, by coating the package 20. Furthermore, the flange 14d of the protective member 14 formed by drawing process has high coplanarity, and thus the flange 14d is able to be loaded by using a mounting machine.

The memory card 1 of this embodiment is able to be used for a mobile electronic device such as a digital still camera, a mobile phone, a PDA, a portable game machine, a portable television, a portable radio, a noncontact type IC card, and an electronic diary; and a nonportable electronic device such as a television, a video recorder, a phone, a refrigerator, a microwave, a machine tool, a card device, and a car.

Further, the memory card 1 may have various functions other than the foregoing close wireless communication function and the foregoing memory function. For example, the memory card 1 may have a noncontact type IC card's personal authentication, a settlement function, a cardkey function, a position detection function, a communication/call function, a password storage function, a function as a main/sub CPU (Central Processing Unit) and the like. Further, the memory card 1 may have a function as a display section by mounting a display unit (liquid crystal, OLCD or the like). In other words, the memory card 1 is able to demonstrate various functions other than storage according to needs.

3. Application Example of the Memory Card

A description will be hereinafter given of an example that the foregoing memory card 1 is applied to an electronic device such as a digital still camera.

FIG. 11 illustrates a signal processing system in the memory card 1.

In the semiconductor chip of the semiconductor package 10B, the memory section 39, the controller section 37, the card side connector section 16 (card side terminal 18), and the package side terminal 30 are provided. The card side connector section 16 is jointed with an electronic device (digital still camera 101). The card side connector section 16 is jointed with an electronic circuit of the digital still camera 101 and becomes an input/output contact for an information signal (a command signal or a data signal), and supplies electric power from the digital still camera 101 to the controller section 37. The digital still camera 101 is able to give a command to the controller section 37 through the card side connector section 16. The controller section 37 sends a certain command to the memory section 39 and the communication component 13 according to the given command.

The memory section 39 stores a given information signal according to the command from the controller section 37, or outputs a stored information signal to the controller section 37 in response to the command from the controller section 37. In the memory section 39, various information used for processing of the communication component 13 (for example, ID information or the like) is stored.

The mounting substrate 10A includes an oscillation circuit 43, a power block 45, an RF block 47, and an antenna 49 together with the communication component 13.

The controller section 37 and the communication component 13 are electrically connected with each other through the package side terminal 30 on the semiconductor package 10B side and the substrate side terminal 32 on the communication component 13 side. Specifically, the controller section 37 and the communication component 13 are connected with each other through the package side terminal 30 and the substrate side terminal 32, and input/output a command signal/an information signal. The communication component 13 is able to receive an information signal from the memory section 39 through the controller section 37, and is able to input/output a command signal/an information signal from/to the electronic device (digital still camera 101).

The communication component 13 functions as a center for performing control and processing to demonstrate the close wireless transfer function. Specifically, the communication component 13 controls operation of the RF block 47, and performs various processing (for example, decryption and information conversion) for a wireless communication signal obtained from the RF block 47. The communication component 13 is connected to the oscillation circuit 43, and a certain frequency signal is input therein. The oscillation circuit 43 sends out, for example, 20 MHz frequency. The power block 45 receives a VDD signal obtained from the controller section 37, and forms a current of several types of voltages (for example, 3.3 V, 1.8 V, and 1.2 V) that is necessary for the communication component 13. The formed current is supplied to the communication component 13. The RF block 47 is composed of various electronic components (for example, a power amplifier and a modulation section) for wireless communication controlled by the communication component 13.

The antenna 49 is provided on the opposite side of the side where the mounting substrate 10A is connected to the semiconductor package 10B out of the front face of the mounting substrate 10A. The antenna 49 is able to perform radio communication only within a certain distance.

Relation with the Digital Still Camera 101

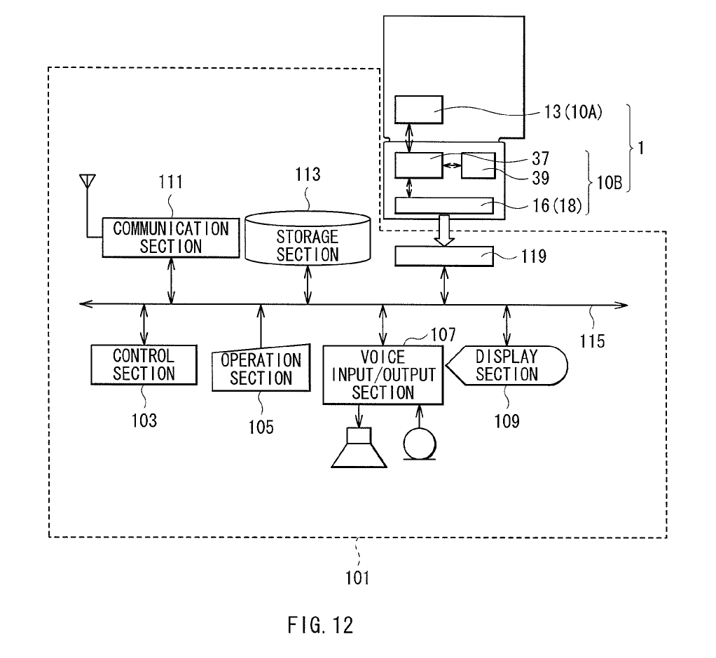

FIG. 12 illustrates a signal processing system of the digital still camera 101 connected to the memory card 1.

In the digital still camera 101, each component is commonly connected to a system bus 115 composed of a plurality of lines for address, data, and control. The respective components are specifically a control section 103 as a center of control and processing, an operation section 105, a display section 109, a camera section 106, and a storage section 113. Further, in the system bus 115, a slot side connector 119 is formed. The digital still camera 101 inputs/outputs an information signal and a command signal from/to the memory card 1 through the slot side connector 119.

The camera section 106 captures an external video as a moving image or a still image. The captured video is output as an image information signal to the control section 103. The control section 103 performs various processing for the image information signal, and displays the image on the display section 109 if necessary. The camera section 106 is able to perform shutter speed change, optical zoom and the like.

The operation section 105 receives user direction input through a plurality of operation keys and the like. In the case where these keys are operated by the user, the operation section 105 generates a signal corresponding to the operation content, and outputs the signal as user direction to the control section 103. The display section 109 is composed of, for example, LCD or OLED (organic light emitting diode), and displays an image according to a video signal supplied from the control section 103. The user operates the operation section 105 while viewing the image displayed on the display section 109, and changes lightness, angle, magnification ratio, zoom, shutter speed and the like of the camera section 106.

The storage section 113 stores various data used for various processing of the digital still camera 101. For example, the storage section 113 stores various processing programs and data used by the digital still camera 101. The storage section 113 mainly stores basic data used by the digital still camera 101. Image information captured by the camera section 106 is stored in the memory section 39 of the memory card 1. The control section 103 overall controls entire operation (various processing) of the digital still camera 101. In particular, the control section 103 controls writing information to the memory section 39 of the memory card 1 and reading information from the memory section 39, controls the communication component 13, and executes various programs for more effectively using the communication component 13. According to circumstances, the control section 103 makes the display section 109 display various information and makes the storage section 113 store various information.

In such a digital still camera 101, as illustrated in FIG. 13, the memory card 1 is inserted and loaded into the slot 117 provided in a body side substrate 115 or the like. Therefore, the memory card 1 is jointed with an electronic circuit or the like formed on the body side substrate 115, and plays the foregoing various functions.

A slot side connector 119 is formed in a position that is located on the deeper side in the direction of inserting the memory card 1 of the slot 117 and that is on the body side substrate 115 side. In the slot side connector 119, a slot side terminal 121 is formed to match with the shape of the groove 17 of the memory card 1. The slot side terminal 121 is electrically connected to an electronic circuit of the body side substrate 115. In other words, the slot side terminal 121 functions as an interface through which information is sent and received between the memory card 1 and the electronic circuit of the electronic device to which the memory card 1 is connected.

In the case where the memory card 1 is inserted into the slot 117, the slot side terminal 121 and the card side terminal 18 are electrically connected, and therefore the electronic circuit of the digital still camera 101 and the controller section 37 of the memory card 1 are electrically jointed, and therefore input/output of an information signal is enabled.

While the description has been given of the invention with reference to the embodiment, the invention is not limited to the foregoing embodiment, but various modifications may be made.

For example, the shape of the protective member 14 is not limited to the shape illustrated in FIG. 3, but is able to be change variously according to the size of a mounted component and shape of a mounted region. Further, in the invention, the description has been given of the thin card device as an example that effectively demonstrates reinforcement effect of the foregoing mounting substrate. However, the invention is not limited to such a thin card device, but is able to be applied to a device having a stereoscopic shape. In other words, in the specification, “card device” includes a device having a given thickness (stereoscopic device) as well.

The first cabinet 20A and the second cabinet 20B are an example of the cabinet of the invention. The cabinet of the invention may be any type as long as the cabinet corresponds to a case (package) that contains the mounting substrate 10A and the semiconductor package 10B.

The present application contains subject matter related to that disclosed in Japanese Priority Patent Application JP 2010-017116 filed in the Japanese Patent Office on Jan. 28, 2010, the entire contents of which is hereby incorporated by reference.

It should be understood by those skilled in the art that various modifications, combinations, sub combinations and alternations may occur depending on design requirements and other factors insofar as they are within the scope of the appended claims or the equivalents thereof.

What is claimed is:

1. A card device comprising:
a package;
a mounting substrate on which an electronic component is mounted and which is contained in the package; and
a protective member jointed with the mounting substrate so as to cover at least part of the electronic component,
wherein the protective member forms a containable space by a ceiling section and a side wall, has a curve section at a joint section between a rim of the ceiling section and the side wall, and shows higher rigidity than that of the mounting substrate.

2. The card device according to claim 1, wherein the protective member is formed by drawing process of a sheet metal.

3. The card device according to claim 1, wherein the mounting substrate has a ground region around a mounting region of the electronic component, and the protective member has a flange jointed with the side wall, and the flange is jointed with the ground region.

4. The card device according to claim 1, wherein the protective member is provided with plating treatment, and the resultant protective member is jointed with a ground region of the mounting substrate by solder.

5. The card device according to claim 1, wherein the protective member has an electromagnetic shield function.

6. The card device according to claim 1, wherein the package has a pair of a first cabinet and a second cabinet, and
the package contains the mounting substrate in a space formed by the first cabinet and the second cabinet.

7. The card device according to claim 1, wherein the electronic component has a wireless communication function.

8. The card device according to claim 1, further comprising a semiconductor package having a memory function, wherein
the semiconductor package is jointed with the mounting substrate by being overlapped with a region other than a mounting region of the electronic component.

9. The card device according to claim 8, wherein the semiconductor package includes a card side connector including a card side terminal for inputting/outputting an information signal on a joint face side with the mounting substrate and a package side terminal in a position where the semiconductor package is overlapped with the mounting substrate,
the mounting substrate has a substrate side terminal in a position where the mounting substrate is overlapped with the semiconductor package,
the semiconductor package and the mounting substrate are electrically jointed by the package side terminal and the substrate side terminal, and
overlap joint between the semiconductor package and the mounting substrate is shifted so that the card side connector is exposed.
